(19) United States
(12) Patent Application Publication
(10) Pub. No.: US 2010/0009548 A1
(43) Pub. Date: Jan. 14, 2010

(54) METHOD FOR HEAT-TREATING SILICON WAFER

(75) Inventors: Kozo Nakamura, Nagasaki (JP); Seiichi Shimura, Nagasaki (JP); Tomoko Nakajima, Nagasaki (JP)

Correspondence Address: KRATZ, QUINTOS & HANSON, LLP, 1420 K Street, N.W., Suite 400, WASHINGTON, DC, 20005, US

(73) Assignee: SUMCO TECHXIV CORPORATION, Omura-shi, Nagasaki (JP)

(21) Appl. No.: 12/438,786

(22) PCT Filed: Aug. 21, 2007
(86) PCT No.: PCT/JP2007/066190

§ 371 Date: Feb. 25, 2009

(30) Foreign Application Priority Data
Aug. 25, 2006 (JP) 2006-229095

(51) Int. Cl. H01L 21/26

(52) U.S. Cl. 438/795; 257/E21.328

(57) ABSTRACT

Provided is a heat treatment method wherein generation of slip dislocation in silicon wafer RTP is suppressed, in order to solve a problem of not sufficiently suppressing generation of slip dislocation of silicon wafers in conventional RTP. A step is provided for suspending temperature rising for 10 seconds or longer at a temperature in a range of over 700° C. to below 950° C., so as to prevent generation of slip dislocation during rapid heating, at least at a silicon wafer portion that contacts with a supporting section of a rapid heating apparatus or at a portion on the outermost circumference section of the silicon wafer.

### TECHNICAL FIELD

The present invention relates to a process for heat-treating a silicon wafer obtained by slicing a silicon single crystal ingot manufactured with the Czochralski method.

### BACKGROUND ART

As wafers for fabricating IC devices such as a semiconductor integrated circuit, there have been employed silicon single crystal wafers (hereinafter, referred to as silicon wafer), which are manufactured by subjecting a silicon single crystal ingot grown mainly with the Czochralski method (hereinafter, referred to as CZ method) to slicing, grinding or other processes.

In manufacturing processes of the IC devices, a rapid heating/rapid cooling process (Rapid Thermal Process: hereinafter, this thermal process is referred to as RTP) of silicon wafers has been widely used as a thermal treatment for activating the doping elements that are ion-implanted to the silicon wafers. In this RTP, the doping elements introduced in an n-layer or p-layer of the silicon wafers are activated by rapid heating.

This RTP is performed by using an RTA (Rapid Thermal Annealer) apparatus.

The RTA apparatus is a heat-treating apparatus in which the silicon wafer is supported by a supporting section in the RTA apparatus, and then the supported silicon wafer is rapidly heated by using infrared lamps. As a generally used method for supporting the silicon wafer, there exist a method using plural support pins to support a rear surface of the silicon wafer, and a method using a susceptor to support a circumference section of the silicon wafer. After rapidly heated to a high temperature, the silicon wafer is cooled at a prescribed cooling rate by adjusting an electric power applied to the infrared lamps as needed.

The RTP using the RTA apparatus above is also employed for a thermal treatment in which defect-free portions are formed in a front surface layer of the silicon wafer while oxygen precipitates (Bulk Micro Defect: BMD) are formed in the interior of the silicon wafer.

The BMD is formed by oxygen precipitates (SiO₂), and is capable of trapping detrimental heavy metals that contaminated the silicon wafer in the fabrication process of the IC devices. Therefore, in order to improve the yield of the IC devices, the BMD is introduced to the silicon wafer.

The patent literature 1 below discloses a process in which defect-free portions are formed in the front surface layer of the silicon wafer with the rapid heating, and the BMD is formed in the interior of the silicon wafer with the rapid cooling. The desired BMD is obtained by rapidly heating the silicon wafer from a room temperature to about 1250° C. at a rate of about 100° C./sec, and then rapidly cooling the silicon wafer, for example, at a cooling rate of 50° C./sec or faster. This process utilizes a phenomenon in which the atom vacancies are frozen only in the interior of the wafer by maintaining a high temperature of 1250° C. to introduce a high concentration of atom vacancies to the silicon wafer and then rapidly cooling the silicon wafer. In other words, this process has a feature in which, by utilizing an effect that the atom vacancies facilitate the generation of the oxygen precipitates, the front surface is caused to be the defect-free layer where no BMD exists, and the high concentration of BMD that has the effect of trapping the heavy metals is formed in the interior of the silicon wafer.

However, in the case of the patent literature 1, a thermal stress occurs in the silicon wafer due to the rapid heating of the silicon wafer. As described later, this thermal stress is more likely to cause slip dislocation at a silicon wafer portion that contacts with the supporting section of the RTA apparatus.

Furthermore, as to a silicon wafer having the large diameter of 300 mm, a stress caused by its own weight also increases. Thus, in the case of the RTP with the patent literature 1, in addition to the generation of the slip dislocation due to the thermal stress, the generation of the slip dislocation due to the stress by its own weight is inevitable.

(Regarding Slip Dislocation)

The slip dislocation generated in the silicon wafer with the RTP will be described.

FIG. 1 is a schematic diagram showing pin-marks and edge-damages on the silicon wafer.

As shown in FIG. 1, when three supporting pins are used to support the back surface of the silicon wafer, three pin-marks P1-P3 are generated on the back surface of the silicon wafer.

Minute crystal defect portions, called dislocation (dislocation cluster), are generated in the proximity of the pin-marks. Additionally, at the time of transporting the silicon wafer, (plural) edge-damages P4 randomly occur at various portions in the proximity of the circumference section of the silicon wafer. Minute dislocation (dislocation cluster), which becomes a cause of the slip dislocation, also occurs in the vicinity of the edge-damages.

FIGS. 2A and 2B are X-ray topographs in the proximity of the pin-mark after the RTP.

In FIG. 2A, only a pin-mark having about 0.5 mm diameter and generated by contacting with a pin can be seen at a center portion of the photograph. This is an example of a case where any expansion or development of the slip dislocation does not occur. In FIG. 2B, two slip dislocations, which expand and develop in two directions from the pin-mark due to the RTP, can be seen. The sizes of the two slip dislocations are about 8 mm and about 5 mm, respectively.

FIG. 3 is an X-ray topograph in the proximity of the edge of the silicon wafer after the RTP.

In FIG. 3, three slip dislocations, which expand and develop in a direction toward the center of the silicon wafer from three edge-damages P4, can be seen. Each size of the slip dislocations is about 5 mm.

As described above and shown in FIGS. 2B and 3, the minute dislocations (dislocation cluster) on the rear surface or at the edge portion of the silicon wafer existing before the RTP expand and develop to become large slip dislocations by the thermal stress occurring in the RTP.

If the slip dislocation is generated in the silicon wafer, the silicon wafer becomes warped. Additionally, the slip dislocation causes leaks in the IC devices, which significantly deteriorates the yield of the IC devices. Thus, there has been a strong demand for suppressing the generation of the slip dislocation in the RTP of the silicon wafer.

Under such circumstance, the patent literatures 2 and 3 disclose a method for suppressing the generation of the slip dislocation by changing the ambient gas composition in the RTP.

The patent literature 4 discloses a method for suppressing, by adding nitrogen to the silicon wafer to further strengthen the wafer, the generation of the slip dislocation due to the thermal treatment.

The patent literature 5 discloses a method for suppressing, by adding ammonia (NH3), etc. to the ambient gas to lower the temperature of the RTP, the generation of the slip dislocation in the silicon wafer.

The patent literature 6 discloses a method for suppressing, by modifying the shape of the annular-shaped susceptor that supports the silicon wafer, the generation of the slip dislocation in the RTP.

Additionally, the following non-patent literatures 1-4 relate to research reports on the generation of the slip dislocation in the silicon single crystal.

The non-patent literature 1 provides a report on how a minute dislocation cluster is easily generated at a contact portion with a light load in the silicon single crystal.

The non-patent literature 2 provides a report on a relationship between the dislocation and the shearing stress in the silicon wafer. According to the non-patent literature 2, the shearing stress by which the dislocation starts to move is in proportion to concentration of the interstitial oxygen incorporated in the silicon crystal as solid solution, and the slip dislocation is less likely to occur as the oxygen concentration increases. Additionally, it indicates that the dislocation starts to move by a significantly low shearing stress and hence avoiding the generation of the slip dislocation is difficult.

The non-patent literature 3 provides a report on a relationship of an annealing period of time to the shearing stress by which dislocation starts to move under the circumstance of 647° C. after the dislocation occurring in the silicon single crystal is annealed. The non-patent literature 4 provides a report on a relationship of annealing temperature and time to the shearing stress by which dislocation starts to move under the test temperature of 550° C. after the dislocation occurring in the silicon single crystal is annealed for a prescribed period of time under the temperature range of 350° C. to 850° C.

According to the reports of the non-patent literatures 3 and 4, the dislocation immediately after generated starts to move by a significantly low shearing stress. Additionally, while being in motion, the dislocation keeps moving under a significantly low shearing stress. On the other hand, at the time of annealing the dislocation, oxygen atoms in the silicon single crystal gather to the dislocation, and then significantly strengthen the shearing stress by which the dislocation starts to move.

In the case of the non-patent literatures 3 and 4, the dislocation in the silicon single crystal is annealed for prescribed period of times, and then, the relationship between the dislocation and the shearing stress is evaluated under the certain temperature environment. Thus, those literatures are not directed to suppressing the generation of the slip dislocation at the silicon wafer portion that contacts with the supporting section of the RTA apparatus and at the edge portion on the outermost circumference of the silicon wafer during the process of rapidly raising the temperature of the silicon wafer to about 1250° C.

Patent literature 1: Japanese Patent Application Laid-open (Translation of PCT application) No. 2001-59319
Patent literature 2: Japanese Patent Application Laid-open No. 11-135514
Patent literature 3: Japanese Patent Application Laid-open No. 2002-110685
Patent literature 4: Japanese Patent Application Laid-open No. 2002-43241
Patent literature 5: Japanese Patent Application Laid-open No. 2003-31582
Patent literature 6: Japanese Patent Application Laid-open No. 2002-134593
Non-patent literature 1: Kyoko Minowa and Koji Sumino, Physical Review Letters, Volume 69, (1992) p. 320
Non-patent literature 2: Dimitris Mroudas and Robert A. Brown, Journal of Minerals Research, Volume 6 (1991) p. 2337
Non-patent literature 3: Koji Sumino and Masato Imai, Philosophical Magazine A, Volume 47, No. 5 (1983) p. 783
Non-patent literature 4: S. Senkader and P. R. Wilshaw, Journal of Applied Physics, Volume 89 (2001) p. 4803

### DISCLOSURE OF THE INVENTION

### Problems to be Solved by the Invention

The present inventors, etc. have earnestly examined the suppression of the generation of the slip dislocation in the silicon wafer during the RTP. As a result, they have learned that the conventional arts cannot sufficiently suppress the generation of the slip dislocation in the silicon wafer.

Especially, when the silicon wafer having a diameter of 300 mm is subjected to the RTP, its own weight is heavy and the thermal stress increases due to the large temperature difference in the surface. Therefore, it is difficult to suppress the generation of the slip dislocation at the silicon wafer portion that contacts with the supporting section of the RTA apparatus and at the edge portion on the outermost circumference of the silicon wafer. Additionally, the temperature during the RTP for introducing BMD excesses as high as 1200° C., and this high temperature lasts a long period of time. This condition is severe for the slip, and hence the slip related to the pin-mark is unavoidable.

The present invention has been made in view of the problem above and the object of the present invention is to provide a method for heat-treating silicon wafer, in which the generation of the slip dislocation is suppressed in the RTP of the silicon wafer.

### Means to Solve the Problems

To achieve the object above, a first aspect of the present invention provides a feature in which temperature rising is suspended for 10 sec or longer at a temperature in a range of over 700° C. to less than 950° C. to prevent generation of a slip dislocation during a rapid heating process at least at a silicon wafer portion that contacts with a supporting section of a rapid heating apparatus or a portion on an outermost circumference section of the silicon wafer.

A second aspect of the present invention provides a feature in which temperature rising is suspended for 10 sec or longer at a temperature range other than 700° C. or lower and 900° C. or over to prevent generation of a slip dislocation during a rapid heating process at least at a silicon wafer portion that contacts with a supporting section of a rapid heating apparatus or a portion on an outermost circumference section of the silicon wafer.

The first and the second aspects of the present invention provide a thermal treatment method for significantly suppressing expansion or development of slip dislocation that unavoidably occurs in a silicon wafer during RTP.

According to the reports in the non-patent literatures 3 and 4, the dislocation immediately after being generated and the dislocation that is in motion are moved by a significantly low shearing stress. On the other hand, by annealing the dislocation in a certain temperature range, oxygen atoms in the silicon single crystal gather to the dislocation. This significantly strengthens the shearing stress by which the dislocation starts to move.

However, the non-patent literatures 3 and 4 are directed to evaluating a relationship between the dislocation and the shearing stress under a certain temperature environment after the silicon single crystal is annealed for a prescribed period of time, and do not provide any knowledge about the suppression of the slip dislocation generation during the process of rapidly raising a silicon wafer temperature to as high as about 1250° C.

In the present invention, a temperature-rising step is found for suppressing the generation of the slip dislocation in the silicon wafer at a silicon wafer portion that contacts with a supporting section of the RTA apparatus and in an edge portion on the outermost circumference of the silicon wafer, at the time of a rapid-heating thermal treatment of the silicon wafer. And, the present invention provides a thermal treatment method in which this temperature-rising step is incorporated into the RTP.

More specifically, as shown in FIG. 5B, temperature rising is suspended for 10 seconds or longer at a prescribed temperature-rising-suspension temperature to suppress the movement of the dislocation, while the dislocation generated in the silicon wafer is annealed during the temperature-rising-suspension time to make the oxygen atoms in the silicon wafer gather to the dislocation.

A third aspect of the present invention provides a feature according to the first or the second aspect of the present invention, in which ambient gas of the thermal treatment is gas mixed of argon gas and nitrogen gas.

According to the third aspect of the present invention, in addition to the effect provided by the first or the second aspect of the present invention, since nitrogen gas is mixed as ambient gas, a surface of the silicon wafer can be strengthened (hardened) during the temperature rising.

A fourth aspect of the present invention provides a feature according to the first or the second aspect of the present invention, in which ambient gas of the thermal treatment is gas mixed of argon gas and ammonia gas.

According to the fourth aspect of the present invention, in addition to the effect provided by the first or the second aspect of the present invention, since ammonia gas is mixed as the ambient gas, the thermal treatment effect same as that of the higher retention temperature can be obtained, even if a high-temperature-retention temperature is low. This is because the ammonia gas has a function of encouraging the introduction of vacancy to the silicon wafer.

A fifth aspect of the present invention provides a feature according to any one of the first to the fourth aspects of the present invention, in which, after the step of suspending the temperature rising, temperature is heated to a prescribed temperature at a temperature-rising rate of about 90° C./sec; and after a temperature is maintained at a prescribed temperature for a certain period of time, temperature is cooled at a cooling rate of about 50° C./sec.

According to the fifth aspect of the present invention, after the temperature-rising-suspension time, the silicon wafer can be heated at a high rate of about 90° C./sec. Additionally, since the silicon wafer is cooled at a relatively low cooling-rate, oxygen in the silicon wafer can sufficiently move.

A sixth aspect of the present invention provides a feature according to any one of the first to the fifth aspects of the present invention, in which the prescribed temperature is in a range of 1200° C. to 1250° C.

According to the sixth aspect of the present invention, an appropriate high-temperature-retention temperature can be selected as needed in accordance with a type of ambient gas.

A seventh aspect of the present invention provides a feature according to the first to the sixth aspect of the present invention, in which a diameter of the silicon wafer is 300 mm or larger.

According to the seventh aspect of the present invention, this method can be applied to the RTP of the silicon wafer having a large diameter.

An eighth aspect of the present invention provides a feature according to the first or the second aspect of the present invention, in which the rapid-heating thermal treatment of the silicon wafer is performed as a pre-treatment in preparation for a step of forming oxygen precipitates.

### EFFECTS OF THE INVENTION

According to the first and the second aspects of the present invention, by setting a prescribed temperature-rising-suspension time in a temperature-rising step, oxygen atoms in the silicon wafer can gather to a dislocation cluster. This makes it possible to strengthen the shearing stress by which the dislocation starts to move, and to significantly suppress the expansion and development of the dislocation to become the slip dislocation during temperature rising thereafter. Accordingly, the high-quality silicon wafer having been subjected to the RTP can be easily manufactured.

According to the third aspect of the present invention, since the surface of the silicon wafer can be strengthened, it is possible to further suppress the dislocation to expand and develop to the slip dislocation.

According to the fourth aspect of the present invention, the high-temperature-retention temperature can be lowered, it becomes possible to shorten the entire thermal treatment process and to alleviate the thermal load of the RTA apparatus.

According to the fifth aspect of the present invention, since the temperature is raised at a high rate, it becomes possible to optimally form the defect-free portion in the surface layer of the silicon wafer, while, since the cooling rate is optimized such that the oxygen can be sufficiently moved in the silicon wafer, desired oxygen precipitates can be formed in the silicon wafer.

According to the sixth aspect of the present invention, by setting the appropriate high-temperature-retention temperature as needed, the generation of the slip dislocation can be further suppressed.

According to the seventh aspect of the present invention, it is possible to manufacture the further high-quality silicon wafer having a large diameter through the RTP treatment.

According to the eighth aspect of the present invention, since the oxygen precipitates are formed by using the silicon wafer in which the slip dislocation is suppressed, the oxygen precipitates formation with the high yields can be achieved.

### BEST MODE FOR CARRYING OUT THE INVENTION

Hereinafter, the RTP of the silicon wafer according to the present invention will be described with reference to the drawings.

(Regarding RTA Apparatus)

First, an RTA (RTA: Rapid Thermal Annealer) apparatus employed in the RTP in the present invention will be described.

FIG. 4 is a schematic diagram illustrating the RTA apparatus employed in the RTP of the silicon wafer.

In FIG. 4, the RTA apparatus 10 has a chamber 12 made of a quartz plate 11, and the thermal treatment of the silicon wafer 13 is performed within the chamber 12. Infrared lamps 14,14 are disposed so as to surround the chamber 12 from the upper and the down sides, and apply heat. Electric power for each of the infrared lamps 14,14 is independently supplied and controlled.

The silicon wafer 13 is placed on three support pins 18 provided on a quartz table 17. Note that an annular-shaped susceptor may be employed instead of the support pins 18.

The chamber 12 is provided with a gas introduction port 15 for introducing ambient gas for thermal treatment, and a gas exhaust port 16 for discharging the ambient gas.

Additionally, a temperature of the silicon wafer 13 is measured with non-contact measurement by using an infrared thermometer, which is located outside the chamber 12 and not shown.

The RTP with the RTA apparatus above can be divided mainly into the following six steps.

(1) Supporting the silicon wafer 13 with the three support pins 18 provided in the chamber 12.

(2) Seamlessly flowing the ambient gas for the thermal treatment from a right-side allow direction A to a left-side allow direction B in order to thermally treat the silicon wafer in a prescribed mixed gas environment.

(3) Heating the silicon wafer with the infrared lamps 14,14 at a prescribed temperature-rising rate, and raising its temperature to a high-temperature-retention temperature T0. Hereinafter, this step is referred to as “temperature-rising step.”

(4) Maintaining the high temperature for a prescribed period of time at the high-temperature-retention temperature T0. During this step, atom vacancies are introduced to the silicon wafer.

(5) Stopping the heating with the infrared lamps, and rapidly cooling the wafer. During this step, the atom vacancies in the surface layer of the silicon wafer are diffused to the outside to disappear, and a large number of the atom vacancies are frozen only in the interior of the wafer. As a result, during the thermal process in the fabrication process of the IC devices, a state where the oxygen precipitates (BMD) are formed only in the interior of the wafer can be created.

(6) After rapid cooling, taking the silicon wafer 18 out from the chamber 12.

(Generation Process of Slip Dislocation)

In a case of the RTP above, it has been difficult to avoid the generation of slip dislocation at the silicon wafer portion that contacts with the supporting section of the RTA apparatus.

Then, the present inventors, etc. have earnestly examined the generation process of the slip dislocation in the silicon wafer during the RTP, and have considered the generation process of the slip dislocation as mentioned below.

First, when the silicon wafer contacts with the support pin, the annular-shaped susceptor or the like, a contact damage occurs at a contacting portion on the silicon wafer. This contact damage is an unavoidable damage occurring even by a slight contacting load, and the minute dislocation cluster (cluster of dislocation) is generated at the contacting portion. In addition to the contacting portion as described above, the edge damage is unintentionally left in a case when the wafer edge contacts to transport the wafer, which becomes a starting point of the generation of the slip dislocation. As the generated dislocation clusters and the edge damage are minute and occur on the rear side or at the edge portion of the silicon wafer, the dislocation clusters and the edge damage themselves are not deleterious. The non-patent literature 1 provides a report on how the minute dislocation clusters occur on the contacting portion at the time of slight contact.

However, the dislocation in the cluster starts to move by the shearing stress due to the thermal stress occurring during the temperature-rising step, and expands and develops thereafter. When the dislocation largely expands or develops, it becomes noticeable as slip dislocation reaching several tens millimeters in some cases.

On the other hand, the non-patent literature 2 indicates that the shearing stress by which the dislocation starts to move is in proportion to the interstitial oxygen concentration, which is in solution in the silicon crystal, and also describes that the dislocation starts to move by a significantly low shearing stress.

The present inventors, etc. focused on the phenomenon described in the non-patent literatures 3 and 4.

According to the non-patent literatures 3 and 4, the dislocation immediately after being generated starts to move by the significantly low shearing stress. Additionally, while being in motion, the dislocation keeps their motion by the significantly low shearing stress. On the other hand, by annealing the dislocation, the oxygen atoms in the silicon wafer gather to the dislocation. This significantly strengthens the shearing stress by which the dislocation starts to move.

This suggests that, by annealing at a constant temperature the dislocation clusters generated in the silicon wafer, the effect that the expansion and development of the dislocation is suppressed during the temperature-rising step thereafter can be obtained.

However, the non-patent literatures 3 and 4 are directed to evaluating a relationship between the dislocation and the shearing stress under a certain temperature environment after the dislocation in the silicon single crystal is annealed for a prescribed period of time, and are not directed to suppressing the slip dislocation generation at the silicon wafer portion that contacts with the supporting section of the RTA apparatus and at the edge portion on the outermost circumference of the silicon wafer during the process of rapidly raising a silicon wafer temperature to as high as about 1250° C.

Then, the present inventors, etc reached the idea that, if an annealing condition that causes the oxygen atoms in the silicon wafer to gather to the dislocation during the RTP can be found, the generation of the slip dislocation in the silicon wafer can be suppressed by applying the annealing condition to the RTP.

On the basis of the idea above, the present invention has been made as a result of earnestly carrying out experiments to find the annealing condition for the RTP of the silicon wafer. Hereinbelow, the RTP of the present invention will be described.

(RTP of the Present Invention)

The present invention is made by devising the temperature-rising step of the (3) above.

FIG. 5A is a diagram illustrating the conventional RTP. FIG. 5B is a diagram illustrating the RTP of the present application. The horizontal axis represents time S (arbitrary), while the vertical axis represents temperature T (arbitrary). It should be note that, in the figures, a prescribed temperature T0 is set in the range from 1200° C. to 1250° C.

As shown in FIG. 5A, in a case of the conventional RTP, during the temperature-rising step, the silicon wafer is rapidly heated while the temperature-rising rate is being kept at a high temperature-rising rate (A portion in the figure), such that the temperature reaches a high-temperature-retention temperature T0 with high speed. After the temperature reaches the high-temperature-retention temperature T0, such state is maintained for a prescribed period of time (B portion in the figure). Then, the silicon wafer is rapidly cooled (C portion in the figure).

On the other hand, in a case of the present invention, as shown in FIG. 5B, the silicon wafer is heated to a temperature-rising-suspension temperature T1 in the range of over 700° C. to less than 950° C. (D portion in the figure), rather than being rapidly heated to the prescribed temperature T0 in one single step. Next, at the temperature-rising-suspension temperature T1, temperature rising is suspended for 10 seconds or longer (E portion in the figure; referred to as temperature-rising-suspension time). After the end of the temperature-rising-suspension time, rapid heating is carried out again up to the high-temperature-retention temperature T0 (F portion in the figure). In this case, the temperature-rising rate is set from 50° C./sec to 90° C./sec. After reaching the high-temperature-retention temperature T0, the process is maintained to this state for a certain period of time (G portion in the figure). The period of time for maintaining the high-temperature-retention temperature T0 is from 5 seconds to 30 seconds. Then, the silicon wafer is rapidly cooled (H portion in the figure). In this case, the cooling rate is about 50° C./sec.

As described above, the present invention is characterized in that, during the temperature-rising step in the RTP of the silicon wafer, the temperature-rising-suspension time of 10 seconds or longer is set at the temperature-rising-suspension temperature T1 in the range of over 700° C. to less than 950° C. It should be note that the temperature-rising-suspension time is only necessary to be 10 seconds or longer, and the length thereof may be changed as needed.

With this temperature-rising-suspension time, the generation of the slip dislocation in the silicon wafer in the next rapid heating, which reaches the high-temperature-retention temperature T0, can be significantly suppressed. It is assumed that this is because oxygen atoms in the silicon wafer gather to the dislocation (dislocation cluster) during the temperature-rising-suspension time; this significantly strengthens the shearing stress by which the dislocation starts to move; and hence the movement of the dislocation occurring during the temperature rising thereafter is significantly suppressed.

As described above, according to the present invention, since, in the RTP, the temperature-rising-suspension time is set in the temperature-rising step of the silicon wafer, the generation of the slip dislocation can be significantly suppressed. As a result, with the RTP of the present invention, the high-quality silicon wafer without having the slip dislocation can be easily manufactured.

### First Example

In the First Example, as a silicon wafer to be evaluated, a silicon wafer having oxygen concentration of 14×10¹⁷ atoms/cm³ (old ASTM) with a diameter of 300 mm is prepared. In the RTA apparatus, the silicon wafer is supported by three support pins. Additionally, as the ambient gas to be introduced in the chamber, mixed gas in which 2.5% in the total pressure is formed by nitrogen gas and the remainder in the total pressure is formed by argon gas is employed.

In the temperature-rising step of the RTP, the temperature-rising rate from the room temperature to the temperature-rising-suspension temperature T1 is set to 90° C./sec. The temperature-rising-suspension temperature T1 is set to seven conditions of 700, 750, 800, 850, 900, 950 and 1000° C., and the temperature-rising-suspension times of 5, and 20 seconds are set to each of the six temperature-rising-suspension temperatures except the case of 700° C. To the case of the temperature-rising-suspension temperature of 700° C., the temperature-rising-suspension times of 10, 20 and 60 seconds are set. It should be noted that, for the purpose of comparison, the RTP with the conventional temperature-rising step, which does not include any temperature-rising-suspension time, is also carried out.

The temperature-rising rate from the temperature-rising-suspension temperature T1 to the high-temperature-retention temperature T0 of 1250° C. is set to 90° C./sec. In the next, the high-temperature-retention temperature T0 is maintained for 30 seconds, and then the silicon wafer is cooled at the cooling rate of 50° C./sec.

FIG. 6 shows a result of the slip obtained from an X-ray topograph measurement result of the silicon wafer having been subjected to the RTP with 22 temperature-rising-step patterns in the First Example.

According to FIG. 6, in a case of comparison example 1 in which the temperature-rising-suspension time is not set, the slip dislocation having the 42 mm length in total is generated in the proximity of the support pins. Additionally, three slip portions as shown in FIG. 3 are generated at the edge portion on the outermost circumference of the wafer.

Additionally, in a case of the temperature-rising-suspension temperature of 700° C. (comparison examples 2-4), the slip dislocations are generated in all the silicon wafers. The length of the slip dislocations ranges from 30 mm to 37 mm. Additionally, one to three slip portions as shown in FIG. 3 are generated at the edge portion on the outermost circumference of the wafer. It is assumed that this is because the diffusion rate of oxygen atoms in the silicon wafer is low due to the low temperature-rising-suspension temperature, and hence the oxygen atoms cannot sufficiently move and gather to the dislocation cluster.

Furthermore, in a case of the temperature-rising-suspension temperature of 950° C. or over (comparison examples 9-14), the slip dislocation is generated in all the silicon wafers. The total length of the slip dislocation in the proximity of the support pins ranges from 35 mm to 45 mm. Additionally, one to four slip portions as shown in FIG. 3 are generated at the edge portion on the outermost circumference of the wafer. It is assumed that the reason is that the oxygen atoms do not effectively gather to the dislocation because the high temperature region of 950° C. or over weakens the effect that the dislocation absorbs the oxygen atoms, and hence the expansion and development of the slip dislocation cannot be effectively suppressed.

On the other hand, in a case of the RTP under the annealing condition of the present invention, in other words, in a case of the examples 1-8 of the present invention, it can be understood that each length of the slip dislocations falls into 1-2 mm in any cases. Additionally, there exists no slip portion as shown in FIG. 3 at the edge portion on the outermost circumference of the wafer. More specifically, in the case where the condition of the present invention is used, the expansion and development of the slip dislocation in the silicon wafer is significantly suppressed as compared with the conventional example.

Furthermore, even if the temperature-rising-suspension temperature is in the range from 750° C. to 900° C., the length of the slip dislocations becomes large in any cases when the temperature-rising-suspension time is 5 seconds (comparison examples 5-8). It is considered that the reason is that oxygen atoms cannot sufficiently gather to the dislocation during the temperature-rising-suspension time because the temperature-rising-suspension time was short.

As described above, according to the First Example, by incorporating the temperature-rising step of the present invention into the RTP, oxygen atoms in the silicon wafer can be gathered to the dislocation cluster during suspension of temperature rising. This strengthens the shearing stress of the silicon wafer, and prevents the dislocation from starting to move. As a result, the generation of the slip dislocation in the silicon wafer during the RTP can be significantly suppressed, and the high-quality silicon wafer having been subjected to the RTP can be easily manufactured.

It should be noted that it is desirable that the support pins for supporting the silicon wafer should have a low adhesion tendency to silicon, and that the support pins should be a sharp-tipped quartz pin or be formed of SiC. The same applies to the case of the Second Example.

Additionally, in the First Example, by mixing nitrogen gas in the ambient gas, the surface of the silicon wafer can be strengthened. This provides an effect that, during the temperature-rising step, the expansion and development of the dislocation cluster existing in the proximity of the surface of the silicon wafer to become the slip dislocation can be further suppressed.

FIG. 7 is a diagram showing distribution of BMD density in the depth direction in a case when the thermal treatment is applied to the silicon wafer after the RTP. The horizontal axis represents a distance (μm) from the surface of the wafer, while the vertical axis represents the BMD density (cm⁻²). The thermal treatment is applied at 780° C. for three hours, and at 1000° C. for 16 hours thereafter. The BMD density is obtained by counting etched image of the BMD by using an optical microscope after 2 μm-selection etching is applied with Wright etching solution.

As shown in FIG. 7, it can be understood that a favorable precipitation state in which a defect-free layer exists in a surface layer of the silicon wafer while high density BMD exists in the interior of the silicon wafer can be obtained. Note that, since introduction of atom vacancies in the RTP occurs during the suspension at 1250° C. and is not dependent upon the process of temperature rising to 1250° C. at all, the density of BMD is independent of the temperature-rising step. Thus, the same distribution can be seen in all the conditions. In other words, it can be understood that, according to the present invention, any slip does not occur, and favorable BMD density distribution can be obtained.

### Second Example

In the Second Example, as the silicon wafer to be evaluated, a silicon wafer having the oxygen concentration of 13.5×10¹⁷ atoms/cm³ (old ASTM) with a diameter of 300 mm is prepared. In the RTA apparatus, the silicon wafer is supported by three support pins. Additionally, unlike the First Example, mixed gas in which 10% in the total pressure is formed by ammonia gas and the remainder in the total pressure is formed by argon gas is employed as the ambient gas to be introduced in the chamber.

In the temperature-rising step of the RTP, the temperature-rising rate from the room temperature to the temperature-rising-suspension temperature T1 is set to 90° C./sec. The temperature-rising-suspension temperature T1 is set to seven conditions of 700, 750, 800, 850, 900, 950 and 1000° C., and the temperature-rising-suspension times of 5, and 20 seconds are set to each of the six temperature-rising-suspension temperatures except the case of 700° C. The temperature-rising-suspension times of 10, 20 and 60 seconds are set only to the case of the temperature-rising-suspension temperature of 700° C. It should be noted that, for the purpose of comparison, the RTP with the conventional temperature-rising step, which does not include any temperature-rising-suspension time, is also carried out.

The temperature-rising rate from the temperature-rising-suspension temperature T1 to the high-temperature-retention temperature T0 of 1200° C. is set to 90° C./sec. In the next, the high-temperature-retention temperature T0 is maintained for 20 seconds, and then the silicon wafer is cooled at the cooling rate of 50° C./sec.

FIG. 8 shows a result of the slip obtained from a result of X-ray topograph measurement of the silicon wafer having been subjected to the RTP with 22 temperature-rising-step patterns in the Second Example.

According to FIG. 8, in a case of the temperature-rising-suspension time of 700° C. (comparison example 2-4), the slip dislocation is generated in all the silicon wafers. The total length of the slip dislocation in the proximity of the support pins ranges from 29 mm to 36 mm. Additionally, one to two slip portions as shown in FIG. 3 are generated at the edge portion on the outermost circumference of the wafer. It is assumed that the reason is that the oxygen atoms in the silicon wafer do not sufficiently move and gather to the dislocation due the low temperature-rising-suspension temperature.

Similarly, in a case of the temperature-rising-suspension temperature of 950° C. or over (comparison examples 9-14), the slip dislocation is generated in all the silicon wafers. The total length of the slip dislocation in the proximity of the support pins ranges from 31 mm to 42 mm. Additionally, one to two slip portions as shown in FIG. 3 are generated at the edge portion on the outermost circumference of the wafer. It is assumed that the reason is that the oxygen atoms do not effectively gather to the dislocation because the high temperature region of 950° C. or over weakens the effect that the dislocation absorbs the oxygen atoms, and hence the expansion and development of the slip dislocation cannot be effectively suppressed.

On the other hand, in a case of the RTP under the condition of the present invention, in other words, in a case of the examples 1-8 of the present invention, it can be understood that each length of the slip dislocation falls into 1-2 mm in any cases. Additionally, at the edge portion on the outermost circumference of the wafer, there exists no slip portion as shown in FIG. 3. More specifically, in the case of the Second Example, the expansion and development of the slip dislocation is significantly suppressed as compared with the conventional examples.

As described above, according to the Second Example, as is the case with the First Example, by incorporating the temperature-rising step of the present invention into the RTP, oxygen atoms in the silicon wafer can be gathered to the dislocation cluster during the temperature-rising-suspension time. This strengthens the shearing stress of the silicon wafer, and prevents the dislocation from starting to move. As a result, the generation of the slip dislocation in the silicon wafer with the RTP can be significantly suppressed, which makes it possible to easily manufacture the high-quality silicon wafer.

It should be noted that, in the Second Example, ammonia gas is mixed as the ambient gas. By using the ammonia gas as the ambient gas, even in a low high-temperature-retention temperature, the thermal treatment effect similar to that with the higher retention temperature can be obtained.

FIG. 9 is a diagram showing distribution of BMD density in the depth direction in a case when the thermal treatment is applied to the silicon wafer after the RTP. The horizontal axis represents a distance (μm) from the surface of the wafer, while the vertical axis represents the BMD density (cm⁻²). The thermal treatment is applied at 780° C. for three hours, and at 1000° C. for 16 hours thereafter. The BMD density is obtained by counting etched image of the BMD by using an optical microscope after 2 μm-selection etching is applied with Wright etching solution.

As shown in FIG. 9, it can be understood that a favorable precipitation state in which a defect-free layer exists in a surface layer of the silicon wafer while high density BMD exists in the interior of the silicon wafer can be obtained. It can also be understood that the BMD density similar to that with the process at the temperature of 1250° C. described in the First Example can be obtained at the temperature of 1200° C. It is assumed that this results from the vacancy-introduction effect with the ammonia gas.

Note that, since introduction of atom vacancies in the RTP occurs during the suspension at 1200° C. and is not dependent upon the process of temperature-rising to 1200° C. at all, the density of BMD is independent of the temperature-rising step. Thus, the same distribution can be seen in all the conditions.

Although three support pins are employed in the First and the Second Example for supporting the silicon wafer, the silicon wafer may be supported with an annular-shaped susceptor as needed. Additionally, the temperature-rising rate is set to 90° C./sec in the Examples. However, if the temperature-rising rate is kept in the range from 50° C./sec to 90° C./sec, the defect-free portion can be formed in the surface layer of the silicon wafer while the generation of the slip dislocation is suppressed.

In the Examples above, a description has been made of one example in which 1250° C. is applied in the case of mixed gas of nitrogen gas and argon gas, and 1200° C. is applied in the case of mixed gas of ammonia gas and argon gas. However, the high-temperature-retention temperature may be optionally set to the temperature of 1200° C. or over to 1250° C. in accordance with the desired BMD density.

Additionally, in the Examples above, the oxygen precipitates in the silicon wafer are effectively formed by setting the cooling rate of 50° C./sec. However, the cooling rate may be changed to 50° C./sec or over, or to 50° C./sec or below.

### BRIEF DESCRIPTION OF THE DRAWINGS

FIG. 1 is a schematic diagram showing pin-marks and edge-damages on the silicon wafer.

FIGS. 2A and 2B are X-ray topographs in the proximity of a pin-mark after the RTP.

FIG. 3 is an X-ray topograph in the proximity of the edge of the silicon wafer after the RTP.

FIG. 4 is a schematic diagram illustrating the RTA apparatus in which the RTP method of the silicon wafer according to the present invention is employed.

FIG. 5A is a diagram illustrating the conventional RTP. FIG. 5B is a diagram illustrating the RTP of the present application.

FIG. 6 shows a result of the slip obtained from an X-ray topograph measurement result of the silicon wafer having been subjected to the RTP with 22 temperature-rising-step patterns in the First Example.

FIG. 7 is a diagram showing distribution of BMD density in the depth direction in a case when the thermal treatment is applied to the silicon wafer after the RTP in the First Example.

FIG. 8 shows a result of the slip obtained from a result of X-ray topograph measurement of the silicon wafer having been subjected to the RTP with 22 temperature-rising-step patterns in the Second Example.

FIG. 9 is a diagram showing distribution of BMD density in the depth direction in a case when the thermal treatment is applied to the silicon wafer after the RTP in the Second Example.

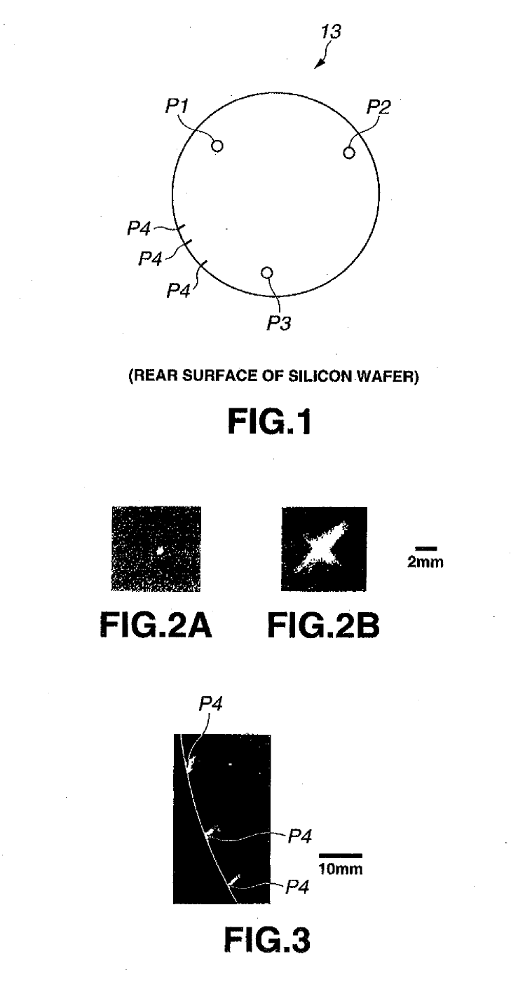

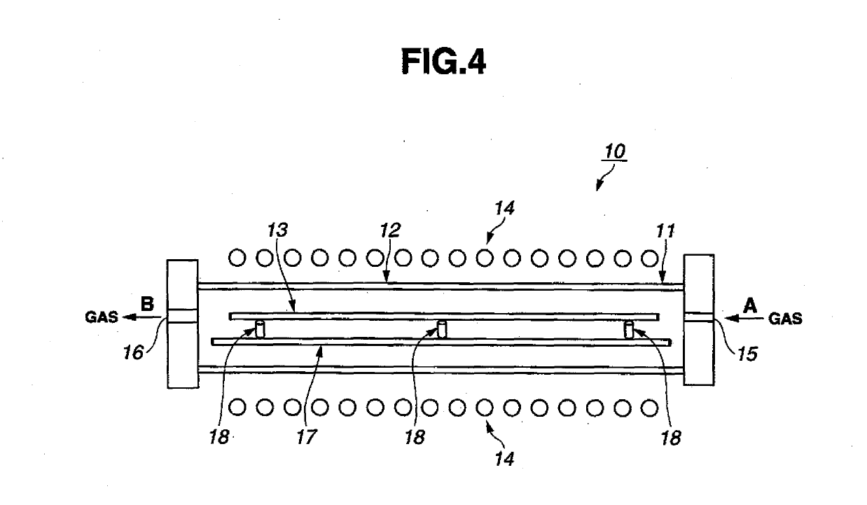

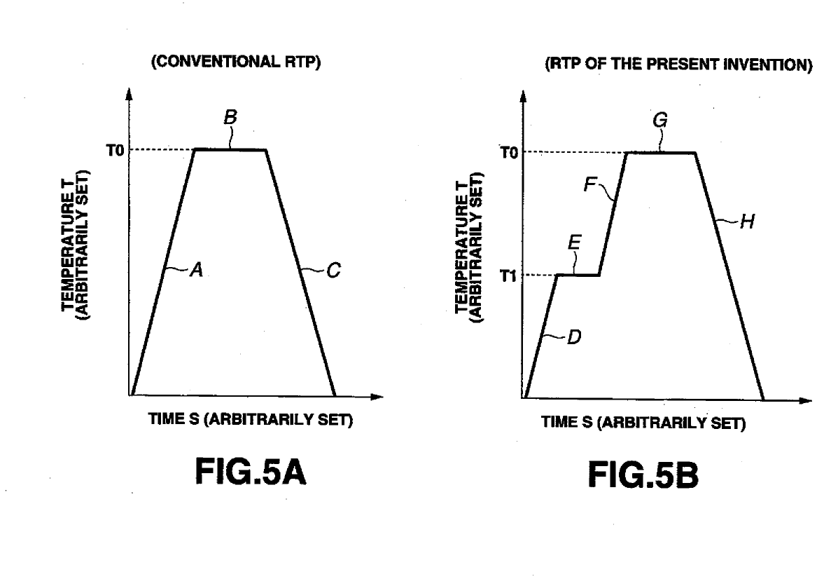

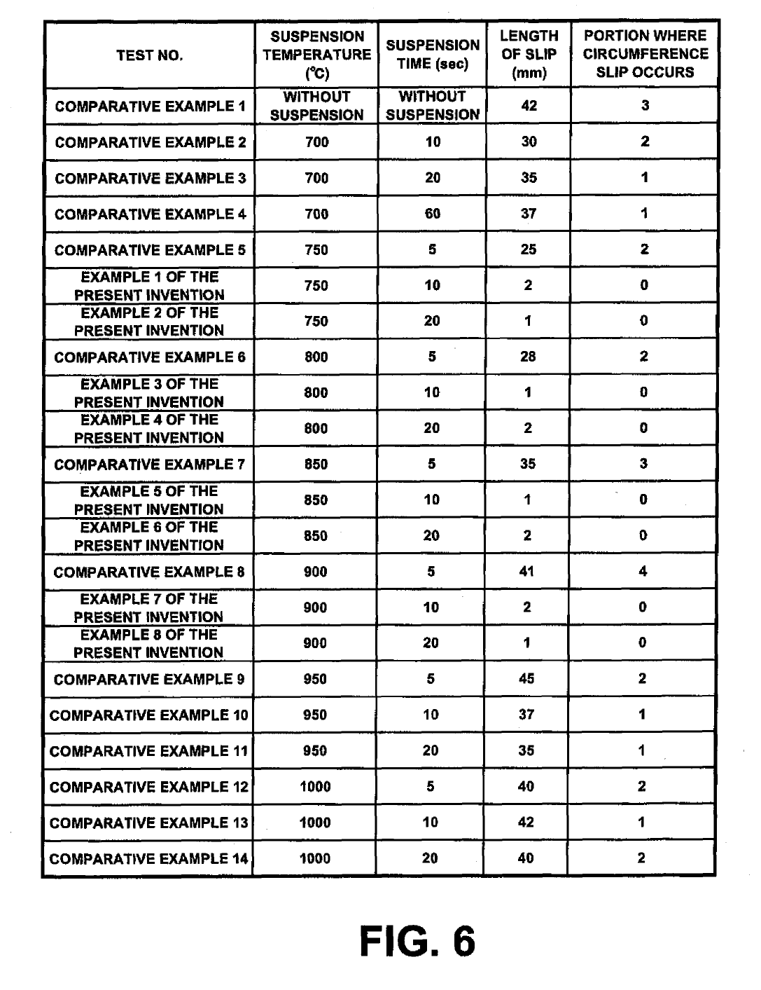

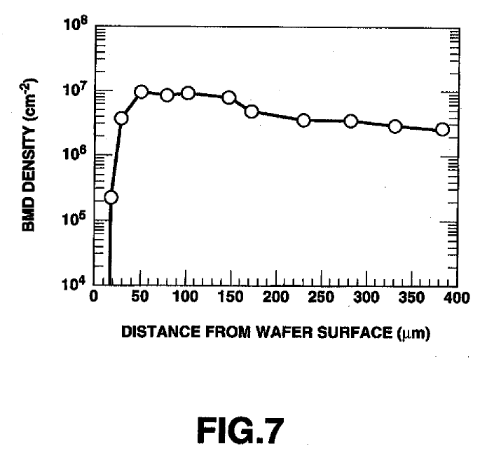

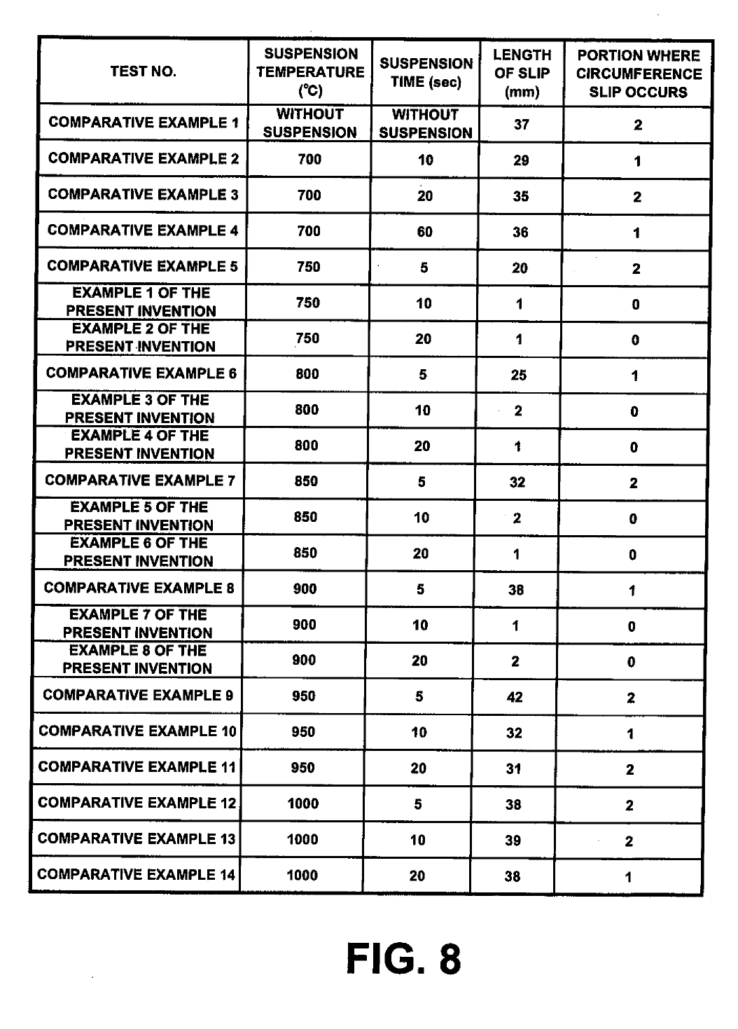

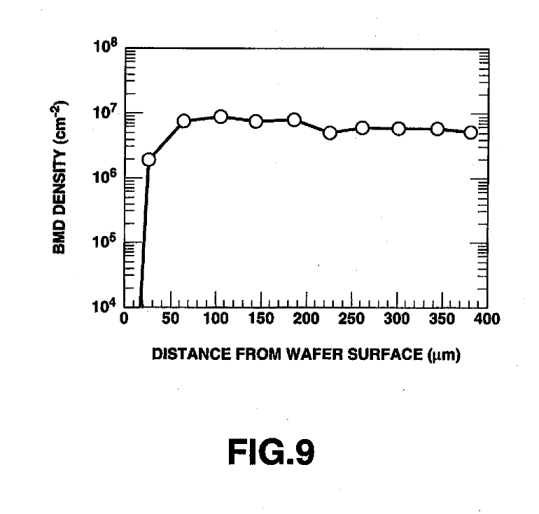

### EXPLANATION OF REFERENCE NUMERALS

10 RTA apparatus
11 Quartz plate
12 Chamber
13 Silicon wafer
14 Infrared lamps
15 Gas introduction port
16 Gas exhaust port
17 Quartz table
18 Support pin

1: A method of a rapid-heating thermal treatment of a silicon wafer, the method comprising: a step of suspending temperature rising for 10 sec or longer at a temperature in a range of over 700° C. to less than 950° C. to prevent generation of a slip dislocation during a rapid heating process at least at a silicon wafer portion that contacts with a supporting section of a rapid heating apparatus or at a portion on an outermost circumference section of the silicon wafer.

2: A method of a rapid-heating thermal treatment of a silicon wafer, the method comprising: a step of suspending temperature rising for to sec or longer at a temperature range excluding the range of 700° C. or lower and 900° C. or over to prevent generation of a slip dislocation during a rapid heating process at least at a silicon wafer portion that contacts with a supporting section of a rapid heating apparatus or at a portion on an outermost circumference section of the silicon wafer.

3: The method of a rapid-heating thermal treatment of a silicon wafer according to claim 2, wherein
ambient gas used in the thermal treatment is mixture gas of argon gas and nitrogen gas.

4: The method of a rapid-heating thermal treatment of a silicon wafer according to claim 2, wherein
ambient gas used in the thermal treatment is mixture gas of argon gas and ammonia gas.

5: The method of a rapid-heating thermal treatment of a silicon wafer according to claim 4, wherein the method comprises
after the step of suspending the temperature rising, a step of raising a temperature to a prescribed temperature at a temperature-rising rate of about 90° C./sec, and
after a temperature is maintained at the prescribed temperature for a prescribed period of time, cooling at a cooling rate of about 50° C./sec.

6: The method of a rapid-heating thermal treatment of a silicon wafer according to claim 5, wherein
the prescribed temperature is in a range of 1200° C. to 1250° C.

7: The method of a rapid-heating thermal treatment of a silicon wafer according to claim 6, wherein
a diameter of the silicon wafer is 300 mm or larger.

8: The method of a rapid-heating thermal treatment of a silicon wafer according to claim 1, wherein
the rapid-heating thermal treatment of the silicon wafer is performed as a pre-treatment for a step of forming oxygen precipitates.

9: The method of a rapid-heating thermal treatment of a silicon wafer according to claim 1, wherein
ambient gas used in the thermal treatment is mixture gas of argon gas and nitrogen gas.

10: The method of a rapid-heating thermal treatment of a silicon wafer according to claim 1, wherein
ambient gas used in the thermal treatment is mixture gas of argon gas and ammonia gas.

11: The method of a rapid-heating thermal treatment of a silicon wafer according to claim 9, wherein the method comprises:
after the step of suspending the temperature rising, a step of raising a temperature to a prescribed temperature at a temperature-rising rate of about 90° C./sec, and
after a temperature is maintained at the prescribed temperature for a prescribed period of time, cooling at a cooling rate of about 50° C./sec.

12: The method of a rapid-heating thermal treatment of a silicon wafer according to claim 11, wherein
the prescribed temperature is in a range of 1200° C. to 1250° C.

13: The method of a rapid-heating thermal treatment of a silicon wafer according to claim 10, wherein the method comprises:
after the step of suspending the temperature rising, a step of raising a temperature to a prescribed temperature at a temperature-rising rate of about 90° C./sec, and
after a temperature is maintained at the prescribed temperature for a prescribed period of time, cooling at a cooling rate of about 50° C./sec.

14: The method of a rapid-heating thermal treatment of a silicon wafer according to claim 13, wherein
the prescribed temperature is in a range of 1200° C. to 1250° C.

15: The method of a rapid-heating thermal treatment of a silicon wafer according to claim 1, wherein the method comprises:
after the step of suspending the temperature rising, a step of raising a temperature to a prescribed temperature at a temperature-rising rate of about 90° C./sec, and
after a temperature is maintained at the prescribed temperature for a prescribed period of time, cooling at a cooling rate of about 50° C./sec.

16: The method of a rapid-heating thermal treatment of a silicon wafer according to claim 15, wherein
the prescribed temperature is in a range of 1200° C. to 1250° C.

17: The method of a rapid-heating thermal treatment of a silicon wafer according to claim 2, wherein the method comprises:
after the step of suspending the temperature rising, a step of raising a temperature to a prescribed temperature at a temperature-rising rate of about 90° C./sec, and
after a temperature is maintained at the prescribed temperature for a prescribed period of time, cooling at a cooling rate of about 50° C./sec.

18: The method of a rapid-heating thermal treatment of a silicon wafer according to claim 17, wherein
the prescribed temperature is in a range of 1200° C. to 1250° C.

19: The method of a rapid-heating thermal treatment of a silicon wafer according to claim 3, wherein the method comprises:
after the step of suspending the temperature rising, a step of raising a temperature to a prescribed temperature at a temperature-rising rate of about 90° C./sec, and
after a temperature is maintained at the prescribed temperature for a prescribed period of time, cooling at a cooling rate of about 50° C./sec.

20: The method of a rapid-heating thermal treatment of a silicon wafer according to claim 18, wherein
the prescribed temperature is in a range of 1200° C. to 1250° C.

21: The method of a rapid-heating thermal treatment of a silicon wafer according to claim 2, wherein
the rapid-heating thermal treatment of the silicon wafer is performed as a pre-treatment for a step of forming oxygen precipitates.
